(19) United States
(12) Patent Application Publication
(10) Pub. No.: US 2002/0135392 A1
(43) Pub. Date: Sep. 26, 2002

(54) Apparatus that probing de-capsulated chip

(76) Inventor: Chih-Hsiung Chang, Hsinchu Hsien (TW)

Correspondence Address: BIRCH STEWART KOLASCH & BIRCH, PO BOX 747, FALLS CHURCH, VA, 22040-0747, US

(21) Appl. No.: 09/814,876

(22) Filed: Mar. 23, 2001

(51) Int. Cl. G01R 31/02

(52) U.S. Cl. 324/765

(57) ABSTRACT

The present invention offers an apparatus that can probe and analyze a de-capsulated chip with probing needles of a probe chuck plate on a fully automatic probe machine. The apparatus is composed of a probe plate that has a first side which is placed on the probe chuck plate, and has a second side that has at least one hollow that the chip can be put in. And the probe plate has one hole passing through the hollow and the first side, in order to catch the chip by the suction of the probe chuck plate through the hole. Then the chip is probed with the probe needles.

### BACKGROUND OF THE INVENTION

1. Field of the Invention

The present invention relates in general to an apparatus that can probe and analyze a de-capsulated chip by probe needles of a probe chuck plate on a fully automatic probe machine.

2. Description of the Related Art

In semiconductor manufacture, the chips are tested and repaired within a wafer together, and split up into chip level for package assembly. The packaged chips are not guaranteed to be functional as they were in the front-end in wafer level. Therefore, there is always a necessary to analyze these failed components in the backend to improve or increase the test coverage of the front-end wafer level to reduce the yield loss in the backend.

At present, the way that industrial circles analyze the capsulated chip is to de-capsulate the packaged chip, then take out the naked chip, and take the naked chip under the microscope in laboratory.

But the traditional method has some disadvantages, described as follows:

(1) It is difficult to probe the pads on the naked chip exactly under the microscope in the laboratory, so it causes inaccuracy.

(2) Without automatic probing on the chip, to land the tens of probe needles properly on the tiny pads of the chip is always a trouble and time consuming task.

(3) It will need to prepare some extra instruments in the laboratory, so the cost is increased.

(4) Once the component is de-capsulated from package protection, it becomes weak and easy to be damaged when probing manually in the laboratory. In order to solve the problem, one manner is on trial. That is to stick the naked chip on the wafer, then run the test by the fully automatic probe machine at the process in the front end or microscope in the laboratory. But it is difficult to control the flatness by this manner. Namely, while testing the chip by the fully automatic probe machine at the process in the front end or microscope in the laboratory, it is not easy to adjust the focus of lens, so inaccuracy will occur. And, when it is necessary to pull out the chip to do another test, this manner is not appropriate because the pulling out process will destroy the chip easily.

### SUMMARY OF THE INVENTION

An object of the present invention is to provide an apparatus that can probe and analyze a de-capsulated chip using probe needles of a probe chuck plate on a fully automatic probe machine. On one hand, the present invention decreases the probability of destroying chip by manually probing. On the other hand, the present invention makes the testing on a fully automatic probe machine, and makes the analysis exactly and efficiently. Further, when the testing is finished, it is easy to pull out the chip from the apparatus of the present invention to do another test.

In order to achieve these purposes, the present invention refers to an apparatus that allows probing and analysis of a de-capsulated chip by using probing needles of a probe chuck plate on a fully automatic probe machine. The apparatus is composed of a probe plate that has a first side which is placed on the probe chuck plate, and has a second side that has at least one hollow that the chip can be put in. And the probe plate has one hole passing through the hollow and the first side, in order to catch the chip by the suction of the probe chuck plate through the hole. Then the chip is probed by the probe needles.

### BRIEF DESCRIPTION OF THE DRAWINGS

The present invention can be more fully understood by reading the subsequent detailed description in conjunction with the examples and references made of the accompanying drawings, wherein:

FIG. 1 is a schematic view of an apparatus of the present invention;

FIG. 2 is a sectional diagram of an embodiment of the present invention;

### DETAILED DESCRIPTION OF THE PREFERRED EMBODIMENT

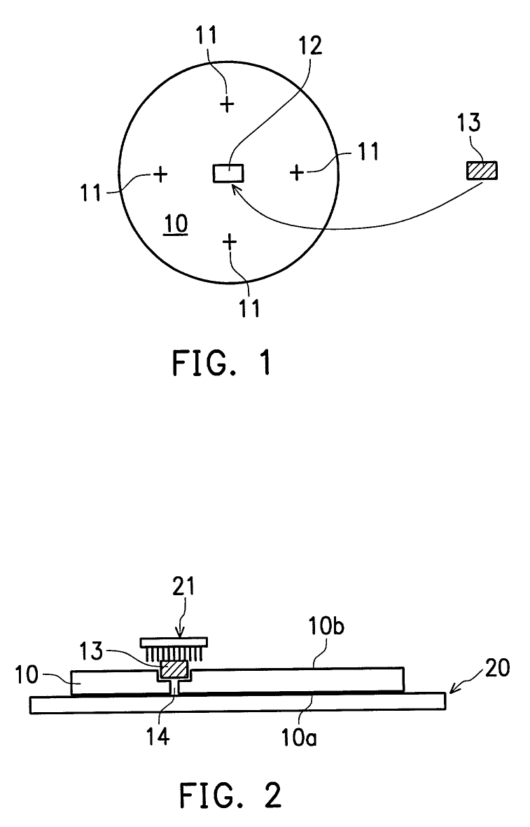

Referring now to FIG. 1 and 2. The present invention refers to an apparatus. The apparatus is used to place a de-capsulated chip 13. The apparatus is applied to testing by probe needles 21 of a probe chuck plate 20 on a fully automatic probe machine. The apparatus includes: a probe plate 10 that has the first side 10a which is placed on the probe chuck plate 20, and has the second side 10b that has at least one hollow 12 that the chip 13 can be put in. And the probe plate 10 has one hole 14 pass through the hollow 12 and the first side 10a, in order to catch the chip 13 by the suction of the probe chuck plate 20 through the hole 14. Then the probe needles 21 probe the chip 13. And the depth of the hollow that is on the second side of the probe plate is smaller than the thickness of the chip.

Refer now to FIGS. 1 and 2. This embodiment is the probe plate 10 with the chip 13 on the probe chuck plate 20 of the fully automatic probe machine, such as TSK maker's model UF-2000 and TEL maker's model P8. Then the chip 13 is caught and fixed through the hole 14 by vacuum. Next, the fully automatic probe machine can by means of the alignment marks 11 in FIG. 1 to determine the position of the probe plate 10 and the chip 13, in order to let the probe needles 21 to aim at the chip 13 exactly for probing.

Here it must be emphasized is that the size of the hollow 12 of the probe plate 10 can be made in a different size, in order to match the chip 13 which is needed for probing. And the quantity of the hollow 12 of the probe plate 10 can be plural. So no matter how many chips 13 on the hollow of the probe plate 10, all the chips can use the apparatus of this invention to be tested in the same fully automatic probe machine. That greatly ameliorates the inconvenient situation of the prior art.

In accordance with the present invention, it greatly ameliorates the inconvenient situation of the prior art, and also improves the accuracy and reliability for analysis, improves efficiency, and saves a lot of cost. So the present invention has progress and practicability.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An apparatus for placing de-capsulated chip, that is applied to testing by probe needles of a probe chuck plate on a fully automatic probe machine, including:
a probe plate that has a first side which is placed on the probe chuck plate, and has a second side that has at least one hollow that the chip can be put in, and the probe plate has one hole passing through the hollow and the first side, in order to catch the chip by the suction of the probe chuck plate through the hole, then probing the chip by the probe needles.

2. The apparatus as claimed in claim 1, wherein the probe plate that has at least one alignment marking device, in order to determine the position of the probe plate and the chip.

3. The apparatus as claimed in claim 2, wherein the alignment marking device is one type of V-notch, flatness edge, line, score or hole.

4. The apparatus as claimed in claim 1, wherein the material of the probe plate is one type of stainless, glass, quartz, silicon wafer or plastic.

5. The apparatus as claimed in claim 1, wherein the depth of the hollow that is on the second side of the probe plate is smaller than the thickness of the chip.
